(19) United States
(12) Patent Application Publication
(10) Pub. No.: US 2018/0190532 A1
(43) Pub. Date: Jul. 5, 2018

(54) FILM FOR SEMICONDUCTOR BACK SURFACE

(71) Applicant: FURUKAWA ELECTRIC CO., LTD., Tokyo (JP)

(72) Inventors: Jirou SUGIYAMA, Tokyo (JP); Masami Aoyama, Tokyo (JP)

(73) Assignee: FURUKAWA ELECTRIC CO., LTD., Tokyo (JP)

(21) Appl. No.: 15/905,888

(22) Filed: Feb. 27, 2018

Related U.S. Application Data
(63) Continuation of application No. PCT/JP2016/068031, filed on Jun. 17, 2016.

(30) Foreign Application Priority Data
Sep. 16, 2015 (JP) 2015-182394

(51) Int. Cl. H01L 21/683; H01L 23/31

(52) U.S. Cl. CPC H01L 21/6836; H01L 23/3192; H01L 24/81; H01L 2221/68327; H01L 2221/68377; H01L 23/3171

(57) ABSTRACT

Provided is a film for semiconductor protection, which can prevent warpage in a semiconductor wafer or a semiconductor chip and can also prevent the occurrence of chipping or ref low cracking. The film for semiconductor protection of the invention has a metal layer to be stuck to the back surface of a semiconductor chip, and an adhesive layer for adhering the metal layer to the back surface of the semiconductor chip, the surface free energy of the face of the adhesive layer on the side that is adhered to the semiconductor chip and the surface free energy of the face on the side that is adhered to the metal layer are together 35 mJ/m² or greater, and the peeling force between the adhesive layer in the B-stage state and the metal layer is 0.3 N/25 mm or higher.

### TECHNICAL FIELD

The present invention relates to a film for semiconductor back surface, and more particularly, the invention relates to a film for semiconductor back surface, the film being intended to be stuck to the back surface of a semiconductor chip that is mounted by a face down method.

### BACKGROUND ART

In recent years, there is a further increasing demand for thickness reduction and size reduction of semiconductor devices and packages thereof. Semiconductor devices have been manufactured using a mounting method referred to as so-called face down method. In the face down method, a semiconductor chip having formed thereon convex-shaped electrodes called bumps, which are intended for securing conduction to the circuit surface, is used, and a structure in which the circuit surface is reversed (faced down) and then the electrodes are connected to the substrate (so-called flip-chip connection) is employed. In such a semiconductor device, the back surface of the semiconductor chip is protected by a film for semiconductor back surface, and thereby, damage to the semiconductor chip or the like may be prevented (see Patent Document 1). Furthermore, identifiability of manufactured products may also be improved by subjecting this film for semiconductor back surface to laser marking (see Patent Document 2).

According to a representative procedure of flip-chip connection, solder bumps or the like that have been formed on the front surface of a semiconductor chip having a film for semiconductor back surface adhered thereto, are immersed in a flux subsequently the bumps are brought into contact with an electrode formed on a substrate (if necessary, solder bumps have also been formed on this electrode), and lastly, the solder bumps are melted to implement reflow connection between the solder bumps and the electrode. Fluxes are used for the purpose of cleaning the solder bumps at the time of soldering, prevention of oxidation, improvement of wettability of solder, and the like. Based on the above-described procedure, satisfactory electrical connection between semiconductor chips and a substrate can be established.

Here, a flux is usually attached only to the bump parts; however, depending on the operation environment, there are occasions in which the flux is attached to the film for back surface that has been attached to the back surface of a semiconductor chip. Then, when reflow connection is carried out in a state of having the flux attached to the film for back surface, stains originating from the flux are produced on the surface of the film for back surface, and there is a risk that the appearance characteristics or laser markability may be deteriorated.

Thus, there has been suggested a film for semiconductor back surface, the film being capable of preventing the generation of stains even if a flux is attached thereto and enabling production of a semiconductor device having excellent appearance characteristics, the film including an adhesive layer and a protective layer laminated on this adhesive layer, in which the protective layer is constructed from a heat-resistant resin having a glass transition temperature of 200° C. or higher or a metal (see Patent Document 3).

### CITATION LIST

### Patent Document

Patent Document 1: JP 2007-158026 A

Patent Document 2: JP 2008-166451 A

Patent Document 3: JP 2012-033626 A

### SUMMARY OF THE INVENTION

### Problem to be Solved by the Invention

As described in Patent Document 1 or Patent Document 2, in a case in which a resin containing a radiation-curable component or a thermally curable component is cured by means of radiation or heat and thereby a protective film is formed, since the difference between the thermal expansion coefficients of the protective film after curing and the semiconductor wafer is large, there is a problem that warpage occurs in the semiconductor wafer in the middle of processing or a semiconductor chip. The inventors of the present invention conducted an investigation, and as a result, the inventors found that as described in Patent Document 3, forming a protective layer using a metal contributes to the prevention of warpage in a semiconductor wafer or a semiconductor chip.

However, when the adhesive force of an adhesive layer for adhering a metal protective layer to a semiconductor wafer is not sufficient, and stress relaxation of the adhesive does not occur sufficiently, the adhesion between the semiconductor wafer and the adhesive layer, or the adhesion between the adhesive layer and the protective layer becomes unstable. As a result, there is a problem that at the time of dicing of the semiconductor wafer, detachment occurs between the semiconductor wafer or semiconductor chip and the adhesive layer or between the adhesive layer and the protective layer, and chipping (breakage) occurs in the semiconductor chip. Furthermore, there is a problem that reflow cracks occur between the semiconductor chip and the adhesive layer or between the adhesive layer and the protective layer at the time of packaging, and reliability is decreased.

Thus, an object of the present invention is to provide a film for semiconductor back surface, the film being capable of preventing warpage in a semiconductor wafer or a semiconductor chip and also preventing the occurrence of chipping or reflow cracking.

### Means for Solving Problem

In order to solve the problems described above, the film for semiconductor back surface according to the present invention includes a metal layer to be stuck to the back surface of a semiconductor chip; and an adhesive layer for adhering the metal layer to the back surface of the semiconductor chip, in which the surface free energy of the face of the adhesive layer on the side that is adhered to the semiconductor chip and the surface free energy of the face on the side that is adhered to the metal layer are together 35 mJ/m² or greater, and the peeling force between the adhesive layer in the B-stage state and the metal layer is 0.3 N/25 mm or higher.

In regard to the film for semiconductor back surface, it is preferable that the water absorption rate of the adhesive layer is 1.5 vol % or less.

In regard to the film for semiconductor back surface, it is preferable that the saturated moisture absorption rate of the adhesive layer is 1.0 vol % or less.

In regard to the film for semiconductor back surface, it is preferable that the residual volatile matter content of the adhesive layer is 3.0 wt % or less.

It is preferable that the film for semiconductor back surface has a dicing tape having a base material film and a pressure-sensitive adhesive layer, and the metal layer is provided on the pressure-sensitive adhesive layer.

Furthermore, in regard to the film for semiconductor back surface, it is preferable that the pressure-sensitive adhesive layer is a radiation-curable pressure-sensitive adhesive layer, the pressure-sensitive adhesive force of which is reduced by irradiation with radiation.

### Effect of the Invention

According to the present invention, warpage in a semiconductor wafer or a semiconductor chip can be prevented, and also, the occurrence of chipping or reflow cracking can be prevented.

### BRIEF DESCRIPTION OF DRAWINGS

FIG. 1 is a cross-sectional view schematically illustrating the structure of a film for semiconductor back surface according to an embodiment of the present invention.

FIG. 2A-2D are cross-sectional views for explaining the method of using the film for semiconductor back surface according to an embodiment of the present invention.

### MODE(S) FOR CARRYING OUT THE INVENTION

In the following description, embodiments of the present invention will be explained in detail.

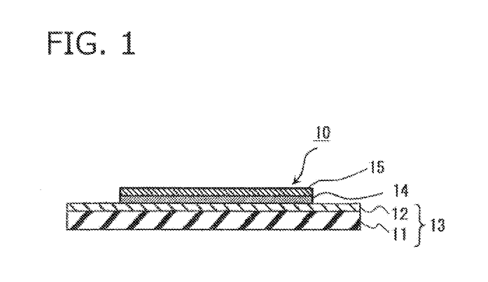

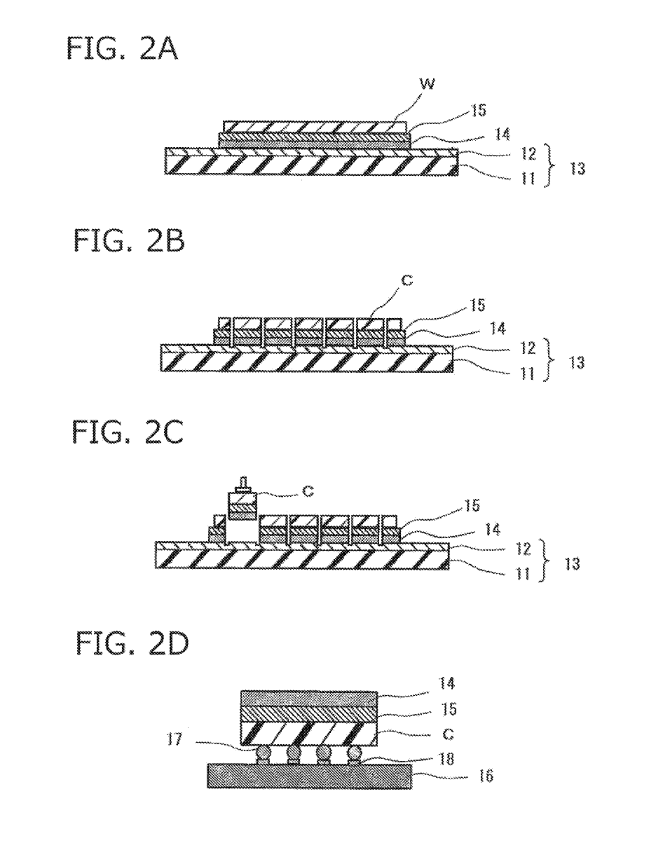

FIG. 1 is across-sectional view illustrating a film for semiconductor back surface 10 according to an embodiment of the present invention. The film for semiconductor back surface 10 of the present embodiment is a dicing tape-integrated type film for semiconductor back surface 10. This film for semiconductor back surface 10 has a dicing tape 13 composed of a base material film 11 and a pressure-sensitive adhesive layer 12 provided on the base material film 11, and on the pressure-sensitive adhesive layer 12, a metal layer 14 for protecting a semiconductor chip C (see FIG. 2), and an adhesive layer 15 provided on the metal layer 14 are provided.

In regard to the adhesive layer 15, it is preferable that the surface on the opposite side of the surface that is brought into contact with the metal layer 14 is protected by a separator (release liner) (not shown in the diagram). The separator has a function as a protective material that protects the adhesive layer 15 until the film for semiconductor back surface is put into actual use. Furthermore, in the case of the dicing tape-integrated type film for semiconductor back surface 10, the separator can be used as a support base material at the time of sticking the metal layer 14 to the pressure-sensitive adhesive layer 12 on the base material film 11 of the dicing tape 13.

The pressure-sensitive adhesive layer 12, the metal layer 14, and the adhesive layer 15 may be cut out (precut) in advance into a predetermined shape in accordance with the process or apparatus used. Furthermore, the film for semiconductor back surface 10 of the present invention may be in the form of being cut out for single sheets of a semiconductor wafer W, or may be in the form obtained by winding a long sheet formed by a plurality of the film for semiconductor back surface 10 cut out for single sheets of the semiconductor wafer W, into a roll shape. In the following description, the various constituent elements will be explained.

### Base Material Film 11

Regarding the base material film 11, any conventionally known base material film can be used without any particular limitations; however, in the case of using a radiation-curable material as the pressure-sensitive adhesive layer 12 that will be described below, it is preferable to use a base material film having radiation transmissibility.

Examples of the material for the base material film include homopolymers or copolymers of α-olefins, such as polyethylene, polypropylene, an ethylene-propylene copolymer, polybutene-1, poly-4-methylpentene-1, an ethylene-vinyl acetate copolymer, an ethylene-ethyl acrylate copolymer, an ethylene-methyl acrylate copolymer, an ethylene-acrylic acid copolymer, and an ionomer, or mixtures thereof; thermoplastic elastomers such as polyurethane, a styrene-ethylene-butene or pentene -based copolymer, and a polyamide-polyol copolymer; and mixtures thereof. Furthermore, the base material film 11 may be a mixture of two or more kinds of materials selected from the group of these materials, and may also be formed from a single layer or multilayer of these materials.

The thickness of the base material film 11 is not particularly limited and may be appropriately set; however, the thickness is preferably 50 to 200 μm.

In order to enhance the adhesiveness between the base material film 11 and the pressure-sensitive adhesive layer 12, the surface of the base material film 11 may be subjected to a chemical or physical surface treatment such as a chromic acid treatment, exposure to ozone, exposure to flame, exposure to high voltage electric shock, or ionizing radiation treatment.

Furthermore, in the present embodiment, the pressure-sensitive adhesive layer 12 is provided directly on the base material film 11; however, the pressure-sensitive adhesive layer 12 may also be provided indirectly, with a primer layer for imparting close adhesiveness, an anchor layer for enhancing the cutting performance at the time of dicing, a stress relieving layer, an antistatic layer, or the like interposed therebetween.

### Pressure-Sensitive Adhesive Layer 12

The resin used for the pressure-sensitive adhesive layer 12 is not particularly limited, and a chlorinated polypropylene resin, an acrylic resin, a polyester resin, a polyurethane resin, an epoxy resin or the like, all of which are known to be used for pressure-sensitive adhesives, can be used. It is preferable that the pressure-sensitive adhesive is prepared by appropriately incorporating an acrylic pressure-sensitive adhesive, a radiation-polymerizable compound, a photopolymerization initiator, a curing agent, and the like to the resin of the pressure-sensitive adhesive layer 12. The thickness of the pressure-sensitive adhesive layer 12 is not particularly limited and may be set as appropriate; however, the thickness is preferably 5 to 30 μm.

A radiation-polymerizable compound can be incorporated into the pressure-sensitive adhesive layer 12, and thereby the pressures-sensitive adhesive layer can be made easily detachable from the metal layer 14 by radiation curing. Regarding the radiation-polymerizable compound, for example, a low molecular weight compound having at least two or more photopolymerizable carbon-carbon double bonds in the molecule, the carbon-carbon double bonds being capable of forming a three-dimensional network by light irradiation, is used.

Specifically, trimethylolpropane triacrylate, pentaerythritol triacrylate, pentaerythritol tetraacrylate, dipentaerythritol monohydroxypentaacrylate, dipentaerythritol hexaacrylate, 1,4-butylene glycol diacrylate, 1,6-hexanediol diacrylate, polyethylene glycol diacrylate, an oligo ester acrylate or the like is applicable.

Furthermore, in addition to the acrylate-based compounds described above, a urethane acrylate-based oligomer can also be used. A urethane acrylate-based oligomer is obtained by reacting a terminal isocyanate urethane prepolymer obtainable by reacting a polyester type or polyether type polyol compound with a polyvalent isocyanate compound (for example, 2,4-tolylene diisocyanate, 2,6-tolylene diisocyanate, 1,3-xylylene diisocyanate, 1,4-xylylene diisocyanate, diphenylmethane-4,4-diisocyanate, or the like), with an acrylate or methacrylate having a hydroxyl group (for example, 2-hydroxyethyl acrylate, 2-hydroxyethyl methacrylate, 2-hydroxypropyl acrylate, 2-hydroxypropyl methacrylate, polyethylene glycol acrylate, or polyethylene glycol methacrylate). The pressure-sensitive adhesive layer 12 may also be a mixture of two or more kinds selected from the above-mentioned resins.

In the case of using a photopolymerization initiator, for example, isopropyl benzoin ether, isobutyl benzoin ether, benzophenone, Michler's ketone, chlorothioxanthone, dodecylthioxanthone, dimethylthioxanthone, diethylthioxanthone, benzyl dimethyl ketal, α-hydroxycylohexyl phenyl ketone, or 2-hydroxymethylphenylpropane can be used. The amount of incorporation of these photopolymerization initiators is preferably 0.01 to 5 parts by mass with respect to 100 parts by mass of the acrylic copolymer.

### Metal Layer 14

The metal that constitutes the metal layer 14 is not particularly limited, and it is preferable that the metal is at least one selected from the group consisting of, for example, stainless steel, aluminum, iron, titanium, tin, and copper, from the viewpoint of laser markability. Among these, stainless steel is particularly preferred from the viewpoint of preventing warpage of a semiconductor wafer W or a semiconductor chip C.

The thickness of the metal layer 14 can be appropriately determined in consideration of prevention of warpage in a semiconductor wafer W or a semiconductor chip C, processability, and the like, and the thickness is usually in the range of 2 to 200 μm, preferably 3 to 100 μm, more preferably 4 to 80 μm, and particularly preferably 5 to 50 μm. When the thickness of the metal layer is 200 μm or more, it is difficult to perform winding, and when the thickness of the metal layer is 50 μm or more, productivity decreases due to the problem of processability. Meanwhile, regarding the effect of suppressing warpage, a thickness of 2 μm or more, at the least, is needed.

### Adhesive Layer 15

The adhesive layer 15 is a product of forming a film of an adhesive in advance, and the surface free energy of the face on the side that is adhered to the semiconductor chip C and the surface free energy of the face on the side that is adhered to the metal layer 14 are together 35 mJ/m² or greater. The surface free energy according to the present invention is a value obtained by measuring the contact angles of water and diiodomethane (liquid droplet volume: water 2 μL, diiodomethane 3 μL, reading time: 30 seconds after dropping) and calculated by the following formula. The surface free energy of the face on the side that is adhered to the semiconductor chip C is, in a case in which a separator or the like has been stuck to the face on the side that is adhered to the semiconductor chip C before use, the surface free energy obtainable after this separator or the like is detached, and the surface free energy of the face on the side that is adhered to the metal layer 14 is the surface free energy obtainable after the metal layer 14 is detached.

$${γ}_{s} = {γ}_{s}^{p} + {γ}_{s}^{d} \\ 72.8 ( 1 + cos {θ}^{H} ) = 2 {( 21.8 {γ}_{s}^{d} )}^{\frac{1}{2}} + 2 {( 51.0 {γ}_{s}^{p} )}^{\frac{1}{2}} \\ 50.8 ( 1 + cos {θ}^{I} ) = 2 {( 48.5 {γ}_{s}^{d} )}^{\frac{1}{2}} + 2 {( 2.3 {γ}_{s}^{p} )}^{\frac{1}{2}} \qquad [ Mathematical Formula 1 ]$$

γₛ: Surface free energy
γₛ^{p}: Polar component of surface free energy
γₛ^{d}: Dispersion component of surface free energy
θ^{H}: Contact angle of water against solid surface
θ^{I}: Contact angle of diiodomethane against solid surface

If the surface free energy of the face of the adhesive layer 15 on the side that is adhered to the semiconductor chip C and the surface free energy of the face on the side that is adhered to the metal layer 14 are less than 35 mJ/m², since sufficient wettability is not obtained, voids can be easily incorporated. Also, the adhesiveness between the metal layer 14 and the adhesive layer 15 becomes insufficient, reflow cracks occur between the semiconductor chip C and the adhesive layer 15 or between the adhesive layer 15 and the metal layer 14, and reliability is lowered. It is practically useful when the surface free energy of the face of the adhesive layer 15 on the side that is adhered to the semiconductor chip C and the surface free energy of the face on the side that I adhered to the metal layer 14 are 55 mJ/m² or less.

Furthermore, the adhesive layer 15 is such that the peeling force (23° C., peeling angle 180 degrees, linear velocity 300 mm/min) between the adhesive layer 15 in the B-stage state (uncured state or semi-cured state) and the metal layer 14 is 0.3 N/25 mm or greater. If the peeling force is less than 0.3 N/25 mm, at the time of dicing of the semiconductor wafer W, detachment occurs between the semiconductor wafer W or semiconductor chip C and the adhesive layer 15 or between the adhesive layer 15 and the metal layer 14, and chipping occurs in the semiconductor chip C.

The water absorption rate of the adhesive layer 15 is preferably 1.5 vol % or less. The method for measuring the water absorption rate is as follows. That is, an adhesive layer 15 (film-like adhesive) having a size of 50×50 mm is used as a sample, and the sample is dried for 3 hours at 120° C. in a vacuum dryer. The sample is left to cool in a desiccator, and then the dry mass is measured and is designated as M1. The sample is immersed in distilled water at room temperature for 24 hours and then is taken out. The sample surface is wiped with a filter paper, and the weight of the sample is quickly measured and is designated as M2. The water absorption rate is calculated by the following Formula (1):

Water absorption rate (vol %)=[(M2−M1)/(M1/d)]×100 (1)

Here, d represents the density of the film.

If the water absorption rate is higher than 1.5 vol %, there is a risk that reflow cracking may occur at the time of solder reflow because of the moisture absorbed.

The saturated moisture absorption rate of the adhesive layer 15 is preferably 1.0 vol % or less. The method for measuring the saturated moisture absorption rate is as follows. That is, a circular-shaped adhesive layer 15 (film-like adhesive) having a diameter of 100 mm is used as a sample, and the sample is dried for 3 hours at 120° C. in a vacuum dryer. The sample is left to cool in a desiccator, and then the dry mass is measured and is designated as M1. The sample is placed in a constant-temperature constant-humidity chamber at 85° C. and 85% RH to allow the sample to absorb moisture for 168 hours, and then the sample is taken out. The weight of the sample is quickly measured and is designated as M2. The saturated moisture absorption rate is calculated by the following Formula (2):

Saturated moisture absorption rate (vol %)=[(M2−M1)/(M1/d)]×100 (2)

Here, d represents the density of the film. If the saturated moisture absorption rate is higher than 1.0 vol %, the value of the vapor pressure becomes high due to moisture absorption at the time of reflow, and satisfactory reflow characteristics may not be obtained.

The residual volatile matter content of the adhesive layer 15 is preferably 3.0 wt % or less. The method for measuring the residual volatile matter content is as follows. That is, an adhesive layer 15 (film-like adhesive) having a size of 50×50 mm is used as a sample, and the initial mass of the sample is measured and is designated as M1. The sample is heated at 200° C. for 2 hours in a hot air-circulating constant temperature chamber, and then the weight of the sample is measured and is designated as M2. The residual volatile matter content is calculated by the following formula (3):

Residual volatile matter content (wt %)=[(M2−M1)/M1]×100 (3)

If the residual volatile matter content is higher than 3.0 wt %, the solvent is volatilized as a result of heating at the time of packaging, and voids are generated in the interior of the adhesive layer 15, the voids causing package cracks.

For the adhesive layer 15, for example, a polyimide resin, a polyamide resin, a polyetherimide resin, a polyamideimide resin, a polyester resin, a polyester imide resin, a phenoxy resin, a polysulfone resin, a polyether sulfone resin, a polyphenylene sulfide resin, a polyether ketone resin, a chlorinated polypropylene resin, an acrylic resin, a polyurethane resin, an epoxy resin, a polyacrylamide resin, or a melamine resin, all of which are known to be used in adhesives, or mixtures thereof can be used. However, from the viewpoints of adhesiveness of the adhesive layer 15 and reliability, it is preferable that the adhesive layer 15 includes an acrylic copolymer and an epoxy resin, and that the acrylic copolymer has a Tg of from 0° C. to 40° C. and a weight average molecular weight of from 100,000 to 1,000,000. The weight average molecular weight is more preferably from 600,000 to 900,000.

Meanwhile, the weight average molecular weight is a value measured by gel permeation chromatography (GPC) method, using a calibration curve based on polystyrene standards.

### Measurement Conditions According to GPC Method

Instrument used: High performance liquid chromatography LC-20AD [manufactured by Shimadzu Corp., trade name]

Column: Shodex Column GPC KF-805 [manufactured by Shimadzu Corp., trade name]

Eluent: chloroform

Measurement temperature: 45° C.

Flow rate: 3.0 ml/min

RI detector: RID-10A

There are no particular limitations on the method for polymerizing an acrylic copolymer, and examples include pearl polymerization, solution polymerization, and suspension polymerization. Thus, copolymers are obtained by these methods. Suspension polymerization is preferred because excellent heat resistance is obtained, and an example of such an acrylic copolymer may be PARACRON W-197C (manufactured by Negami Chemical Industrial Co., Ltd., trade name).

It is preferable that the acrylic copolymer includes acrylonitrile. In the acrylic copolymer, the content of acrylonitrile is preferably 10% to 50% by mass, and more preferably 20% to 40% by mass. When the content of acrylonitrile is 10% by mass or more, the Tg of the adhesive layer 15 can be increased, and adhesiveness can be enhanced. However, when the content of acrylonitrile is 50% by mass or more, fluidity of the adhesive layer 15 becomes poor, and adhesiveness may be deteriorated. An acrylic copolymer including acrylonitrile, which is obtainable by suspension polymerization, is particularly preferred.

The acrylic copolymer may have a functional group in order to enhance adhesiveness. The functional group is not particularly limited; however, examples include an amino group, a urethane group, an imide group, a hydroxyl group, a carboxyl group, and a glycidyl group. Among them, a glycidyl group is preferred. A glycidyl group exhibits satisfactory reactivity with an epoxy, which is a thermosetting resin, and since a glycidyl group does not easily react with the pressure-sensitive adhesive layer 12 compared to a hydroxyl group or the like, a change in the surface free energy does not easily occur.

The adhesive layer 15 may also contain an inorganic filler; however, if the amount of addition is large, fluidity is lowered, and adhesiveness is decreased. Therefore, the content is preferably less than 40% by mass, more preferably less than 20% by mass, and even more preferably less than 15% by mass. Furthermore, if the particle size is large, concavities and convexities are generated on the surface of the adhesive surface, and adhesiveness is decreased. Therefore, the average particle size is preferably less than 1 μm, more preferably less than 0.5 μm, and even more preferably less than 0.1 μm. There are no particular limitations on the lower limit of the particle size of the inorganic filler; however, a particle size of 0.003 μm or larger is practical.

In order to control the surface free energy, a silane coupling agent, a titanium coupling agent, or a fluorine-based graft copolymer may also be added as an additive. It is preferable that the additive contains a mercapto group or a glycidyl group.

The thickness of the adhesive layer 15 is not particularly limited; however, the thickness is usually preferably 3 to 100 μm, and more preferably 5 to 20 μm.

The ratio of the linear expansion coefficient of the metal layer 14 with respect to the linear expansion coefficient of the adhesive layer 15 (linear expansion coefficient of metal layer 14/linear expansion coefficient of adhesive layer 15) is preferably 0.2 or higher. If this ratio is less than 0.2, there is a risk that detachment between the metal layer 14 and the adhesive layer 15 may easily occur, ref low cracks may be produced at the time of packaging, and reliability may deteriorate.

According to the present embodiment, a metal layer 14 is provided directly on the pressure-sensitive adhesive layer 12; however, it is also acceptable that the metal layer 14 is indirectly provided, with a release layer for enhancing the pick-up properties, or a functional layer for being detached, together with the semiconductor chip C, the metal layer 14, and the adhesive layer 15, from the pressure-sensitive adhesive layer 12 and imparting a function to the semiconductor chip C (for example, a heat-dissipating layer), interposed between the pressure-sensitive adhesive layer 12 and the metal layer 14. Furthermore, a functional layer may also be provided between the metal layer 14 and the adhesive layer 15.

### Separator

The separator is intended to improve handleability of the adhesive layer 15 and also to protect an adhesive layer 15. Regarding the separator, a polyester (PET, PBT, PEN, PBN, PTT)-based film, a polyolefin (PP, PE)-based film, a copolymer (EVA, EEA, EBA)-based film, or a film having its adhesiveness or mechanical strength further enhanced by partially substituting these materials, can be used. Furthermore, a laminate of these films may also be used.

The thickness of the separator is not particularly limited and may be appropriately set; however, the thickness is preferably 25 to 50 μm.

### Method for Producing Film for Back Surface

The method for producing a dicing tape-integrated type film for semiconductor back surface 10 according to the present embodiment will be described. First, the adhesive layer 15 can be formed by utilizing a conventionally used method of preparing a resin composition and forming the resin composition into a film-like layer. Specifically, for example, a method of applying the resin composition on an appropriate separator (release paper or the like), drying the resin composition (in a case in which thermal curing is needed, the resin composition is dried by applying a heating treatment as necessary), and forming the adhesive layer 15 may be employed. The resin composition may be a solution or may be a dispersion liquid. Next, the adhesive layer 15 thus obtainable is stuck to a metal layer 14 that has been separately prepared. Regarding the metal layer 14, a commercially available metal foil may be used. Subsequently, the adhesive layer 15 and the metal layer 14 are precut into a circular label shape having a predetermined size using a press-cutting blade, and unnecessary parts in the periphery are removed.

Next, a dicing tape 13 is produced. A base material film 11 can be produced by a conventionally known film-forming method. Examples of the film-forming method include a calendar film-forming method, a casting method in an organic solvent, an inflation extrusion method in a sealed system, a T-die extrusion method, a co-extrusion method, and a dry lamination method. Next, a pressure-sensitive adhesive composition is applied on the base material film 11 and is dried (if necessary, heated and crosslinked), and thereby a pressure-sensitive adhesive layer 12 is formed. Examples of the application method include roll coating, screen coating, and gravure coating. Meanwhile, the pressure-sensitive adhesive layer 12 may be formed on the base material film 11 by applying a pressure-sensitive adhesive layer 12 composition directly on the base material film 11, or it is also acceptable that a pressure-sensitive adhesive composition is applied on a release paper obtained by applying a release treatment to the surface, or the like to form a pressure-sensitive adhesive layer 12, and then the pressure-sensitive adhesive layer 12 is transferred to the base material film 11. Thereby, a dicing tape 13 having a pressure-sensitive adhesive layer 12 formed on a base material film 11 is produced.

Subsequently, the dicing tape 13 is laminated on the separator on which the circular-shaped metal layer 14 and the adhesive layer 15 are provided, such that the metal layer 14 and the pressure-sensitive adhesive layer 12 are brought into contact, and depending on cases, the dicing tape 13 is also precut into a circular-shaped label shape having a predetermined size. Thereby, a dicing tape-integrated type film for semiconductor back surface 10 is produced.

### Use Method

Next, a method for producing a semiconductor device using the dicing tape-integrated type film for semiconductor back surface 10 of the present embodiment will be described with reference to FIG. 2.

The method for producing a semiconductor device includes at least a step of sticking a semiconductor wafer W onto the dicing tape-integrated type film for semiconductor back surface 10 (mounting step); a step of dicing the semiconductor wafer W and forming semiconductor chips C (dicing step); a step of detaching the semiconductor chips C together with the film for semiconductor back surface 10, from the pressure-sensitive adhesive layer 12 of the dicing tape 13 (pick-up step); and a step of flip-chip connecting the semiconductor chips C onto an adherend 16 (flip-chip connection step).

### Mounting Step

First, the separator arbitrarily provided on the dicing tape-integrated film for semiconductor back surface 10 is appropriately detached, and as illustrated in FIG. 2(A), a semiconductor wafer W is stuck to the adhesive layer 15. This is adhered and maintained to be fixed (mounting step). At this time, the adhesive layer 15 is in an uncured state (including a semi-cured state). Furthermore, the dicing tape-integrated type film for semiconductor back surface 10 is stuck to the back surface of the semiconductor wafer W. The back surface of the semiconductor wafer W means the surface on the opposite side of the circuit surface (also referred to as non-circuit surface, non-electrode-formed surface, or the like). The sticking method is not particularly limited; however, a method based on pressure joining is preferred. Pressure joining is usually carried out by pressing with a pressing means such as a pressure roll.

### Dicing Step

Next, as illustrated in FIG. 2(B), dicing of the semiconductor wafer W is carried out. Thereby, the semiconductor wafer W is cut into a predetermined size to divided the wafer into individual pieces (fragmentized), and semiconductor chips C are produced. Dicing is performed according to a conventional method, for example, from the circuit surface side of the semiconductor wafer W. In the present step, for example, a cutting method called full-cut, in which incision is carried out up to the film for semiconductor back surface 10, or the like can be employed. The dicing apparatus used in the present step is not particularly limited, and any conventionally known dicing apparatus can be used. Furthermore, since the semiconductor wafer W is adhered and fixed with excellent adhesiveness by means of the film for semiconductor back surface 10, chip breakage or chip flying can be suppressed, and also, damage of the semiconductor wafer W can also be suppressed. In the case of performing expansion of the dicing tape-integrated type film for semiconductor back surface 10, this expansion can be carried out using a conventionally known expanding apparatus.

### Pick-Up Step

As illustrated in FIG. 3(C), picking up of the semiconductor chips C is performed, and the semiconductor chips C are detached, together with the adhesive layer 15 and the metal layer 14, from the dicing tape 13. The method of picking up is not particularly limited, and various conventionally known methods can be employed. For example, a method of pushing up individual semiconductor chips C from the side of the base material film 11 of the film for semiconductor back surface 10 using needles, and picking up the semiconductor chips C thus pushed up, using a pick-up apparatus, may be employed. Meanwhile, the semiconductor chips C thus picked up are such that the back surfaces of the semiconductor chips are protected by the metal layer 14.

### Flip-Chip Connection Step

The semiconductor chips C thus picked up are fixed, as illustrated in FIG. 3(D), to an adherend 16 such as a substrate by means of the flip-chip bonding method (flip-chip mounting method). Specifically, the semiconductor chips C are fixed to an adherend 16 by a conventional method in a form in which the circuit surfaces (also referred to as front surface, circuit pattern-formed surface, electrode-formed surface, or the like) of the semiconductor chips C face the adherend 16. For example, first, a flux is attached to the bumps 17 as connection parts, which are formed on the circuit surface side of the semiconductor chip C. Next, the bumps 17 of the semiconductor chips C are brought into contact with an electrically conductive material 18 (solder or the like) for joining that are adhered to the connection pad of the adherend 16, and the bumps 17 and the electrically conductive material 18 are melted while being pressed. Thereby, electrical conduction between the semiconductor chips C and the adherend 16 is secured, and thus the semiconductor chips C can be fixed to the adherend 16 (flip-chip bonding step). At this time, a gap is formed between the semiconductor chips C and the adherend 16, and the distance of the gap is generally about 30 μm to 300 μm. Thus, after the semiconductor chips C are flip-chip bonded (flip-chip connected) onto the adherend 16, the flux remaining on the facing surface of the semiconductor chip C and the adherend 16 or remaining in the gaps, is removed by cleaning, and the semiconductor chip C is encapsulated by filling the gap with an encapsulating material (encapsulating resin or the like).

As the adherend 16, various substrates such as a lead frame and a circuit board (wiring circuit board or the like) can be used. The material for such a substrate is not particularly limited; however, examples include a ceramic substrate and a plastic substrate. Examples of the plastic substrate include an epoxy substrate, a bismaleimide-triazine substrate, and a polyimide substrate.

According to the present embodiment, a dicing tape-integrated type film for semiconductor back surface 10 has been explained; however, the film for semiconductor back surface 10 may not be integrated with the dicing tape 13. In the case of a film for semiconductor back surface in which the adhesive layer 15 and the metal layer 14 are not laminated on the dicing tape 13, it is preferable that the face of the adhesive layer 15 on the opposite side of the face that is brought into contact with the metal layer 14 is protected by a separator having a release layer. At the time of use, the separator is detached as appropriate, and the back surface of the semiconductor wafer W is stuck to the adhesive layer 15. In a case in which the adhesive layer 15 and the metal layer 14 are not precut into a predetermined shape, the laminate is cut into a predetermined shape, the metal layer 14 side of the laminate thus obtained is stuck to the pressure-sensitive adhesive layer of the separately prepared dicing tape, and the semiconductor device may be produced by processes similar to those after the dicing step described above.

### EXAMPLES

Next, in order to describe the effects of the present invention more clearly, Examples and Comparative Examples will be explained in detail; however, the present invention is not intended to be limited to these Examples.

(1) Production of Acrylic Polymer

First, the method for producing an acrylic polymer that is included in the adhesive layer of the films for semiconductor back surface according to the various Examples and various Comparative Examples will be described.

### Acrylic Polymer (1)

300 parts by mass of water was introduced into a four-necked round bottom glass flask equipped with a stirrer, and 0.7 parts by mass of polyvinyl alcohol as a dispersion stabilizer was dissolved therein. While the solution was stirred at 300 rpm with a stirring blade, a monomer mixture composed of 65 parts by mass of ethyl acrylate, 23 parts by mass of butyl acrylate, 2 parts by mass of glycidyl methacrylate, and 12 parts by mass of acrylonitrile, and 1 part by mass of N,N′-azobisisobutyronitrile as a polymerization initiator were introduced thereto all at once, and thus a suspension was produced.

While this was continuously stirred, the temperature in the reaction system was raised to 68° C., the temperature was maintained constant for 4 hours, and thus the system was allowed to react. Subsequently, the reaction system was cooled to room temperature (about 25° C.). Next, the reaction product was subjected to solid-liquid separation, the resultant was sufficiently washed with water and dried for 12 hours at 70° C. using a dryer, and subsequently, 2-butanone was added thereto to adjust the solid content to 15%. Thus, acrylic polymer (1) was obtained. The Tg calculated from the mixing ratio was −22° C. The weight average molecular weight of this polymer was 400,000, and the dispersibility was 3.8. The weight average molecular weight was measured by gel permeation chromatography (GPC), using a calibration curve based on polystyrene standards.

### Acrylic Polymer (2)

Acrylic polymer (2) was produced by a production method similar to that for the acrylic polymer (1), except that the content of ethyl acrylate was changed to 43 parts by mass, the content of butyl acrylate was changed to 15 parts by mass, the content of glycidyl methacrylate was changed to 5 parts by mass, and the content of acrylonitrile was changed to 37 parts by mass. The Tg calculated from the mixing ratio was 12° C. The weight average molecular weight of this polymer obtained by gel permeation chromatography was 700,000, and the dispersity was 3.6.

### Acrylic Polymer (3)

Acrylic polymer (3) was produced by a production method similar to that for the acrylic polymer (1), except that the content of ethyl acrylate was changed to 43 parts by mass, the content of butyl acrylate was changed to 15 parts by mass, the content of glycidyl methacrylate was changed to 5 parts by mass, the content of acrylonitrile was changed to 36 parts by mass, and 1 part by mass of a modified silicone oil was added. The Tg calculated from the mixing ratio was 12° C. The weight average molecular weight of this polymer obtained by gel permeation chromatography was 600,000, and the dispersity was 4.0.

### Acrylic Polymer (4)

Acrylic polymer (4) was produced by a production method similar to that for the acrylic polymer (1), except that the content of ethyl acrylate was changed to 34 parts by mass, the content of butyl acrylate was changed to 15 parts by mass, the content of glycidyl methacrylate was changed to 2 parts by mass, and the content of acrylonitrile was changed to 49 parts by mass. The Tg calculated from the mixing ratio was 21° C. The weight average molecular weight of this polymer obtained by gel permeation chromatography was 120,000, and the dispersity was 2.3.

(2) Production of Adhesive Layer

### Adhesive Layer (1)

To 100 parts by mass of the acrylic polymer (1), 25 parts by mass of a cresol novolac type epoxy resin (epoxy equivalent 197, molecular weight 1200, softening point 70° C.), 60 parts by mass of a xylylene novolac resin (hydroxyl group equivalent 104, softening point 80° C.), and 20 parts by mass of a silica filler having an average particle size of 0.045 μm as a filler material were added, and thus a thermally curable adhesive composition was obtained. This adhesive composition was applied on a PET film that served as a separator, and the adhesive composition was dried by heating for 10 minutes at 120° C. Thus, a coating film in the B-stage state having a thickness after drying of 20 μm was formed, and a laminate of PET film/adhesive layer (1)/PET film was obtained.

Regarding the PET film, a silicone release-treated PET film (Teijin, Ltd.: Purex S-314 (trade name), thickness 25 μm) was used.

### Adhesive Layer (2)

Adhesive layer (2) was obtained by a method similar to that for the adhesive layer (1), except that acrylic polymer (2) was used instead of the acrylic polymer (1).

### Adhesive Layer (3)

Adhesive layer (3) was obtained by a method similar to that for the adhesive layer (1), except that acrylic polymer (3) was used instead of the acrylic polymer (1).

### Adhesive Layer (4)

Adhesive layer (4) was obtained by a method similar to that for the adhesive layer (1), except that acrylic polymer (4) was used instead of the acrylic polymer (1).

### Adhesive Layer (5)

Adhesive layer (5) was obtained by a method similar to that for the adhesive layer (1), except that an adhesive composition similar to the previous adhesive layer (1) was applied on a PET film that served as a separator, and the adhesive composition was dried by heating for 6 minutes at 120° C.

(3) Production of Pressure-Sensitive Adhesive Layer Composition

### Pressure-Sensitive Adhesive Layer Composition (1)

To an acrylic copolymer having a weight average molecular weight of 800,000, which was synthesized by radical polymerizing 65 parts by mass of butyl acrylate, 25 parts by mass of 2-hydroxyethyl acrylate, and 10 parts by mass of acrylic acid, adding dropwise 2-isocyanatoethyl methacrylate thereto, and allowing the mixture to react, 3 parts by mass of a polyisocyanate as a curing agent and 1 part by mass of 1-hydroxycyclohexyl phenyl ketone as a photopolymerization initiator were added and mixed therein. Thus, a pressure-sensitive adhesive layer composition (1) was obtained.

### Pressure-Sensitive Adhesive Layer Composition (2)

To an acrylic copolymer having a weight average molecular weight of 800,000, which was obtained by polymerizing 77 pars by mass of 2-ethylhexyl acrylate and 23 parts by mass of 2-hydroxypropyl acrylate, 3 parts by mass of a polyisoyanate as a curing agent was added and mixed therein. Thus, pressure-sensitive adhesive layer composition (2) was obtained.

### Pressure-Sensitive Adhesive Layer Composition (3)

To an acrylic copolymer having a weight average molecular weight of 800,000 obtained by polymerizing 77 parts by mass of 2-ethylhexyl acrylate and 23 parts by mass of 2-hydroxypropyl acrylate, 3 parts by mass of a modified silicone oil as an additive and 3 parts by mass of a polyisocyanate as a curing agent were added and mixed therein. Thus, pressure-sensitive adhesive layer composition (3) was obtained.

(4) Production of Dicing Tape

### Dicing Tape (1)

The pressure-sensitive adhesive layer composition (1) thus produced was applied on a PET film that served as a separator, such that the dried film thickness would be 10 μm, and the applied composition was dried for 3 minutes at 120° C. The pressure-sensitive adhesive layer composition applied on this PET film was transferred onto a polypropylene elastomer (elastomer of PP:HSBR=80:20) resin film having a thickness of 100 μm as a base material film. Thus, dicing tape (1) was produced. Meanwhile, for the polypropylene (PP), NOVATEC FG4 (trade name) manufactured by Japan Polychem Corp. was used, and for the hydrogenated styrene-butadiene (HSBR), DYNARON 1320P (trade name) manufactured by JSR Corp. was used. Furthermore, for the PET film, a silicone release-treated PET film (Teijin, Ltd.: Purex S-314 (trade name), thickness 25 μm) was used.

### Dicing Tapes (2) and (3)

Dicing tape (2) was produced in the same manner as in the case of the dicing tape (1), except that the pressure-sensitive adhesive layer composition (2) was used instead of the pressure-sensitive adhesive layer composition (1). Furthermore, dicing tape (3) was produced in the same manner as in the case of the dicing tape (1), except that the pressure-sensitive adhesive layer composition (3) was used instead of the pressure-sensitive adhesive layer composition (1).

(5) Production of Dicing Tape-Integrated Type Film for Semiconductor Back Surface

### Example 1

The adhesive layer (1) obtained as described above was bonded by lamination to a metal foil made of SUS304 and having a thickness of 50 μm, and thus a laminate was obtained. Furthermore, the pressure-sensitive adhesive film (1) and the laminate were stuck such that the adhesive layer of the laminate was brought into contact with the pressure-sensitive adhesive layer. Thus, a separator-attached film for semiconductor back surface having a base material film, a pressure-sensitive adhesive layer, a metal layer, an adhesive layer, and a separator laminated in this order was obtained. This film for semiconductor back surface was used as a sample of Example 1.

### Example 2

A film for semiconductor back surface of Example 2 was produced by a method similar to that of Example 1, by using the adhesive layer (2) and the pressure-sensitive adhesive film (2) thus obtained.

### Example 3

A film for semiconductor back surface of Example 3 was produced by a method similar to that of Example 1, by using the adhesive layer (3) and the pressure-sensitive adhesive film (2) thus obtained, and using a copper foil having a thickness of 50 μm as the metal layer.

### Comparative Example 1

A film for semiconductor back surface of Comparative Example 1 was produced by a method similar to that of Example 1, by using the adhesive layer (4) and the pressure-sensitive adhesive film (3) thus obtained.

### Comparative Example 2

The adhesive layer (1) and the pressure-sensitive adhesive film (1) thus obtained were used, and these were stuck such that the adhesive layer was brought into contact with the pressure-sensitive adhesive layer. Thus, a separator-attached film for semiconductor back surface having a base material film, a pressure-sensitive adhesive layer, an adhesive layer, and a separator laminated in this order was obtained. This film for semiconductor back surface was used as a sample of Comparative Example 2.

### Comparative Example 3

A film for semiconductor back surface of Comparative Example 3 was produced by a method similar to that of Example 1, by using the adhesive layer (5) and the pressure-sensitive adhesive film (2) thus obtained, and using a copper foil having a thickness of 50 μm as the metal layer.

For the films for semiconductor back surface according to Examples 1 to 3 and Comparative Examples 1 to 3, the following measurement and evaluations were performed. The results are presented in Table 1.

### Surface Free Energy

In regard to the adhesive layer of each of the films for semiconductor back surface according to the Examples and Comparative Examples, the face detached from the separator was designated as face A, and the face detached from the metal layer was designated as face B. The contact angles of water and diiodomethane with respect to these face A and face B were measured (liquid droplet volume: water 2 μL, diiodomethane 3 μL, reading time: 30 seconds after dropping), and from the contact angles of water and diiodomethane obtained by measurement, the surface free energy was calculated using the geometric mean method, based on the following calculation formula. Furthermore, since Comparative Example 2 did not have any metal layer, measurement was not performed.

$${γ}_{s} = {γ}_{s}^{p} + {γ}_{s}^{d} \\ 72.8 ( 1 + cos {θ}^{H} ) = 2 {( 21.8 {γ}_{s}^{d} )}^{\frac{1}{2}} + 2 {( 51.0 {γ}_{s}^{p} )}^{\frac{1}{2}} \\ 50.8 ( 1 + cos {θ}^{I} ) = 2 {( 48.5 {γ}_{s}^{d} )}^{\frac{1}{2}} + 2 {( 2.3 {γ}_{s}^{p} )}^{\frac{1}{2}} \qquad [ Mathematical Formula 1 ]$$

γₛ: Surface free energy
γₛ^{p}: Polar component of surface free energy
γₛ^{d}: Dispersion component of surface free energy
θ^{H}: Contact angle of water against solid surface
θ^{I}: Contact angle of diiodomethane against solid surface

### Peeling Force

The separator of the adhesive layer of each of the films for semiconductor back surface according to the Examples and Comparative Examples was peeled off, and the film for semiconductor back surface was cut out into a short strip having a width of 25 mm. Thus, a specimen having a base material film, a pressure-sensitive adhesive layer, a metal layer, and an adhesive layer laminated in this order was produced. A specimen produced by sticking a shape-retaining tape (manufactured by Sekisui Chemical Co., Ltd., trade name: FORTE) to the surface of the adhesive layer by means of a 2-kg roller, was dividedly grabbed into a laminate of “dicing tape and metal layer” and a laminate of “adhesive layer and reinforcing tape”, by means of a STROGRAPH (VE10) manufactured by Toyo Seiki Seisakusho, Ltd. The peeling force between the adhesive layer and the metal layer was measured at a linear velocity of 300 mm/min. The unit of the peeling force is [N/25 mm]. Furthermore, since Comparative Example 2 had no metal layer, measurement was not performed.

### Water Absorption Rate

The adhesive layer of each of the films for semiconductor back surface according to the Examples and Comparative Examples was cut out into a size of 50×50 mm, and this was used as a sample. The sample was dried for 3 hours at 120° C. in a vacuum dryer, and was left to cool in a desiccator. Subsequently, the dry mass was measured and was designated as M1. The sample was immersed in distilled water for 24 hours at room temperature and then was taken out. The sample surface was wiped with a filter paper, and the weight of the sample was quickly measured and was designated as M2. The water absorption rate was calculated by the following Formula (1):

Water absorption rate (vol %)=[(M2−M1)/(M1/d)]×100 (1)

Here, d represents the density of the film.

### Saturated Moisture Absorption Rate

The adhesive layer of each of the films for semiconductor back surface according to the Examples and Comparative Examples was cut out into a circular shape having a diameter of 100 mm, and this was used as a sample. The sample was dried for 3 hours at 120° C. in a vacuum dryer and was left to cool in a desiccator. Subsequently, the dry mass was measured and was designated as M1. The sample was allowed to absorb moisture in a constant-temperature constant-humidity chamber at 85° C. and 85% RH, and then the sample was taken out. The weight of the sample was quickly measured and was designated as M2. The saturated moisture absorption rate was calculated by the following Formula (2):

Saturated moisture absorption rate (vol %)=[(M2−M1)/(M1/d)]×100 (2)

Here, d represents the density of the film.

### Residual Volatile Matter Content

The adhesive layer of each of the films for semiconductor back surface according to the Examples and Comparative Examples was cut out into a size of 50×50 mm, and this was used as a sample. The initial mass of the sample was measured and was designated as M1. The sample was heated for 2 hours at 200° C. in a hot air-circulated constant-temperature chamber, and then the weight of the sample was measured and was designated as M2. The residual volatile matter content was calculated by the following Formula (3):

Residual volatile matter content (wt %)=[(M2−M1)/M1]×100 (3)

### Chipping

The separator of each of the films for semiconductor back surface according to the Examples and Comparative Examples was peeled off, and the adhesive layer was stuck by heating to a silicon wafer having a thickness of 50 μm for 10 seconds at 70° C. Subsequently, the silicon wafer was diced into chips having a size of 10 mm×10 mm. The diced chips were taken out, and breakage of the chips was measured. A sample having a breakage size of 10 μm or less was rated as “O” as a conforming product, and a sample having a breakage size of more than 10 μm was rated as “X” as a defective product.

### Amount of Chip Warpage

The separator of each of the films for semiconductor back surface according to the Examples and Comparative Examples was peeled off, and the adhesive layer was stuck by heating to a silicon wafer having a thickness of 50 μm for 10 seconds at 70° C. Subsequently, the silicon wafer was diced into chips having a size of 10 mm×10 mm, and the diced laminate was placed on a glass plate. At this time, the laminate was placed such that the chip would come to the glass plate side, and the maximum value of the distance between the laminate and the glass plate was measured. This was designated as the amount of chip warpage.

### Reliability (Number of Cracks Generated Upon Reflow))

The separator of each of the films for semiconductor back surface according to the Examples and Comparative Examples was peeled off, and the adhesive layer was attached to the back surface of a silicon wafer having a thickness of 200 μm. The adhesive layer (1) mentioned above was further stuck to the front surface of the silicon wafer, and the silicon wafer was diced into chips having a size of 7.5 mm×7.5 mm. Subsequently, the diced silicon wafer was mounted on a silver plating-treated lead frame under the conditions of a temperature of 160° C., a pressure of 0.1 MPa, and a time period of 1 second. Furthermore, the resultant was molded using an encapsulating material (KE-1000SV, manufactured by Kyocera Chemical Corp., trade name). Thus, twenty samples were produced for each of the Examples and the Comparative Examples.

Each sample was treated for 196 hours in a constant-temperature constant-humidity layer at 85° C./60 mass % RH, and then a treatment of passing the sample through an IR (infrared) reflow furnace, which was set such that the maximum temperature of the sample surface would be 260° C. for 20 seconds, and cooling the sample by leaving the sample to stand at room temperature, was repeated three times. For the various Examples and the various Comparative Examples, the presence or absence of cracks was observed in the twenty samples that had been treated as described above, and the number of samples in which cracks had been generated out of the twenty samples was counted. When an observation of the presence or absence of cracks was made, each sample was observed by a transmission method using an ultrasonic probe device (Scanning Acoustic Tomograph: SAT), and any detachment observed between various members was all considered as a crack.

TABLE 1

| | | | | Comparative | Comparative | Comparative |
|---|---|---|---|---|---|---|
| | Example 1 | Example 2 | Example 3 | Example 1 | Example 2 | Example 3 |
| Surface energy (face A) | 40 | 55 | 35 | 29 | 40 | 40 |
| Surface energy (face B) | 40 | 49 | 37 | 32 | — | 40 |
| Peeling force (N/25 mm) | 0.7 | 0.9 | 0.3 | 0.4 | — | 0.1 |
| Water absorption rate | 1 | 1.5 | 1 | 0.9 | 1 | 2 |
| Saturated moisture | 0.7 | 1 | 0.7 | 0.7 | 0.7 | 1.4 |
| absorption rate | | | | | | |
| Residual volatile matter | 3 | 3 | 3 | 3 | 3 | 4 |
| content | | | | | | |
| Chipping | ◯ | ◯ | ◯ | ◯ | ◯ | X |
| Chip warpage | 0 mm | 0 mm | 0 mm | 0 mm | 1 mm | 0 mm |
| Cracking upon reflow | 0/20 | 0/20 | 0/20 | 1/20 | 1/20 | 1/20 |

As shown in Table 1, the films for semiconductor back surface according to Examples 1 to 3 were such that the surface free energy of the face of the adhesive layer on the side that was adhered to the semiconductor chip (face A) and the surface free energy of the face on the side that was adhered to the metal layer (face B) were together 35 mJ/m² or greater, and the peeling force between the adhesive layer in the B-stage state and the metal layer was 0.3 N/25 mm or higher. Therefore, satisfactory results were obtained in connection with chipping, chip warpage, and reliability (cracking upon reflow).

In contrast, in regard to the film for semiconductor back surface according to Comparative Example 1, since the surface free energy of the face of the adhesive layer on the side that was adhered to the semiconductor chip (face A) and the surface free energy of the face on the side that was adhered to the metal layer (face B) were less than 35 mJ/m², cracks were generated at the time of reflow. Furthermore, since the film for semiconductor back surface according to Comparative Example 2 did not have any metal layer, warpage occurred in the chips, and due to this warpage, cracks were also generated at the time of ref low. In regard to the film for semiconductor back surface according to Comparative Example 3, since the peeling force between the adhesive layer in the B-stage state and the metal layer was less than 0.3 N/25 mm, detachment occurred between the semiconductor wafer or the semiconductor chip and the adhesive layer or between the adhesive layer and the metal layer at the time of dicing, and chipping (breakage) occurred in the semiconductor chips, while cracks were also generated at the time of reflow.

### EXPLANATIONS OF LETTERS OR NUMERALS

10: Film for semiconductor back surface

11: Base material film

12: Pressure-sensitive adhesive layer

13: Dicing tape

14: Metal layer

15: Adhesive layer

1. A film for semiconductor protection, the film comprising a metal layer to be stuck to the back surface of a semiconductor chip, and an adhesive layer for adhering the metal layer to the back surface of the semiconductor chip,
wherein the surface free energy of the face of the adhesive layer on the side adhering to the semiconductor chip and the surface free energy of the face on the side adhering to the metal layer are together 35 mJ/m² or greater, and
the peeling force between the adhesive layer in the B-stage state and the metal layer is 0.3 N/25 mm or higher.

2. The film for semiconductor protection according to claim 1, wherein the water absorption rate of the adhesive layer is 1.5 vol % or less.

3. The film for semiconductor protection according to claim 1, wherein the saturated moisture absorption rate of the adhesive layer is 1.0 vol % or less.

4. The film for semiconductor protection according to claim 2, wherein the saturated moisture absorption rate of the adhesive layer is 1.0 vol % or less.

5. The film for semiconductor protection according to claim 1, wherein the residual volatile matter content of the adhesive layer is 3.0 wt % or less.

6. The film for semiconductor protection according to claim 2, wherein the residual volatile matter content of the adhesive layer is 3.0 wt % or less.

7. The film for semiconductor protection according to claim 3, wherein the residual volatile matter content of the adhesive layer is 3.0 wt % or less.

8. The film for semiconductor protection according to claim 4, wherein the residual volatile matter content of the adhesive layer is 3.0 wt % or less.

9. The film for semiconductor protection according to claim 1, wherein the film for semiconductor protection has a dicing tape having a base material film and a pressure-sensitive adhesive layer, and the metal layer is provided on the pressure-sensitive adhesive layer.

10. The film for semiconductor protection according to claim 2, wherein the film for semiconductor protection has a dicing tape having a base material film and a pressure-sensitive adhesive layer, and the metal layer is provided on the pressure-sensitive adhesive layer.

11. The film for semiconductor protection according to claim 3, wherein the film for semiconductor protection has a dicing tape having a base material film and a pressure-sensitive adhesive layer, and the metal layer is provided on the pressure-sensitive adhesive layer.

12. The film for semiconductor protection according to claim 4, wherein the film for semiconductor protection has a dicing tape having a base material film and a pressure-sensitive adhesive layer, and the metal layer is provided on the pressure-sensitive adhesive layer.

13. The film for semiconductor protection according to claim 5, wherein the film for semiconductor protection has a dicing tape having a base material film and a pressure-sensitive adhesive layer, and the metal layer is provided on the pressure-sensitive adhesive layer.

14. The film for semiconductor protection according to claim 6, wherein the film for semiconductor protection has a dicing tape having a base material film and a pressure-sensitive adhesive layer, and the metal layer is provided on the pressure-sensitive adhesive layer.

15. The film for semiconductor protection according to claim 7, wherein the film for semiconductor protection has a dicing tape having a base material film and a pressure-sensitive adhesive layer, and the metal layer is provided on the pressure-sensitive adhesive layer.

16. The film for semiconductor protection according to claim 8, wherein the film for semiconductor protection has a dicing tape having a base material film and a pressure-sensitive adhesive layer, and the metal layer is provided on the pressure-sensitive adhesive layer.

17. The film for semiconductor protection according to claim 9, wherein the pressure-sensitive adhesive layer is a radiation-curable pressure-sensitive adhesive layer, the pressure-sensitive adhesive force of the layer being decreased by irradiation with radiation.

18. The film for semiconductor protection according to claim 10, wherein the pressure-sensitive adhesive layer is a radiation-curable pressure-sensitive adhesive layer, the pressure-sensitive adhesive force of the layer being decreased by irradiation with radiation.

19. The film for semiconductor protection according to claim 11, wherein the pressure-sensitive adhesive layer is a radiation-curable pressure-sensitive adhesive layer, the pressure-sensitive adhesive force of the layer being decreased by irradiation with radiation.

20. The film for semiconductor protection according to claim 12, wherein the pressure-sensitive adhesive layer is a radiation-curable pressure-sensitive adhesive layer, the pressure-sensitive adhesive force of the layer being decreased by irradiation with radiation.
